(19) United States
(12) Patent Application Publication
(10) Pub. No.: US 2014/0202519 A1
(43) Pub. Date: Jul. 24, 2014

(54) BROADBAND SUB-WAVELENGTH DIFFRACTIVE OPTICS FOR SOLAR CELLS AND METHODS OF MAKING AND USING THE SAME

(71) Applicant: UNIVERSITY OF SOUTHERN CALIFORNIA, Los Angeles, CA (US)

(72) Inventors: Wei Wu, Los Angeles, CA (US); Yuhan Yao, Los Angeles, CA (US); He Liu, Los Angeles, CA (US)

(73) Assignee: UNIVERSITY OF SOUTHERN CALIFORNIA, Los Angeles, CA (US)

(21) Appl. No.: 13/748,050

(22) Filed: Jan. 23, 2013

(51) Int. Cl. G02B 5/18; H01L 31/052

(52) U.S. Cl. CPC G02B 5/18; H01L 31/0528
USPC 136/246; 359/569; 264/1.7

(57) ABSTRACT

Provided are solar cell assemblies for harvesting solar radiation having a diffractive optic, a reflective surface that directs solar radiation to the diffractive optic, and a plurality of solar converters including a first converter having a first energy conversion efficiency, wherein the diffractive optic directs a first portion of the solar radiation to the first converter and a second portion of the solar radiation to the second converter.

### STATEMENT REGARDING FEDERALLY SPONSORED RESEARCH OR DEVELOPMENT

This invention was made with United States Government support under federal Grant No. DE-SC0001013 as a seedling project at the Center for Energy Science established as an Energy Frontier Research Center by the Department of Energy. The United States Government has certain rights in this invention.

### INTRODUCTION

In the field of solar energy harvesting, recent developments have seen solar efficiency improved by providing solar cells with three junctions arranged in series. See, e.g., W. Guter, et al., “Current-matched triple junction solar cell reaching 41.1% conversion efficiency under concentrated sunlight,” (2009) App. Phys. Lett. 94 (22), 223504, which is incorporated herein in its entirety by reference. However, these solar cells have limitations. First, the materials of the three junctions arranged in series have to be compatible. Second, currents of every junction must match. Third, increasing the number of junctions increases the amount of transmission loss. Fourth, increasing the number of junctions increases the amount of electrical loss due to carrier recombination and serial resistance. The instant invention attempts to overcome these shortcomings by providing a solar cell assembly wherein converters (i.e., solar junctions) are arranged in parallel.

Sub-wavelength dielectric gratings have emerged recently as a promising alternative to distributed Bragg reflection dielectric stacks for high-reflectivity filtering applications. See, e.g., Mateus et al., “Ultrabroadband Mirror Using Low-Index Cladded Subwavelength Grating”, (2004) IEEE Photonics Tech. Let. 16 (2), 518-520; and Chang et al., “Tunable liquid crystal-resonant grating filter fabricated by nanoimprint lithography,” (2007) IEEE Photonic Tech. Lett. 19 (17-20), 1457-1459, each of which is incorporated herein in its entirety by reference.

### SUMMARY

In one aspect, provided are solar cell assemblies for harvesting solar radiation. The solar cell assemblies may comprise a diffractive optic, a reflective surface, and a plurality of solar converters. The reflective surface may direct solar radiation to the diffractive optic. The plurality of solar converters may include a first converter having a first energy conversion efficiency and a second converter having a second energy conversion efficiency. The diffractive optic may directs a first portion of the solar radiation to the first converter and a second portion of the solar radiation to the second converter.

In another aspect, provided are diffractive optics for reflectively distributing a broadband radiation. The broadband radiation may comprise a first range of wavelengths having a first central wavelength and a second range of wavelengths having a second central wavelength longer than the first central wavelength. The diffractive optic may comprise a first dielectric grating and a second dielectric grating. The broadband radiation may enter the diffractive optic through the first dielectric grating. The first dielectric grating may be adapted to reflect at least about 25% of the first range of wavelengths and transmit at least about 25% of the second range of wavelengths. The second dielectric grating may be adapted to reflect at least about 25% of the second range of wavelengths.

In yet another aspect, provided are methods of designing a diffractive optic for reflectively distributing a broadband radiation. The broadband radiation may comprise a first range of wavelengths having a first minimum wavelength, a first maximum wavelength and a first central wavelength and a second range of wavelengths having a second minimum wavelength, a second maximum wavelength and a second central wavelength longer than the first minimum wavelength, first maximum wavelength and first central wavelength, respectively. The method may comprise preparing a plurality of first dielectric gratings by varying a first index of refraction from about 1.5 to about 6, varying a first height from about 20% of the first minimum wavelength to about 200% of the first maximum wavelength, varying a first width pitch from about the first minimum wavelength divided by the first index of refraction to about the first maximum wavelength, and varying a first width from about 0 to about the first pitch, wherein varying the first index of refraction, varying the first height, varying the first width pitch, and varying the first width may be performed with a step size sufficient to ensure that a maximum first reflectivity is detected; preparing a plurality of second dielectric gratings by varying a second index of refraction from about 1.5 to about 6, varying a second height from about 20% of the second minimum wavelength to about 200% of the second maximum wavelength, varying a second pitch from about the second minimum wavelength divided by the second index of refraction to about the second maximum wavelength, and varying a second width from about 0 to about the second width pitch, wherein varying the second index of refraction, varying the second height, varying the second pitch, and varying the second width may be performed with a step size sufficient to ensure that a maximum second reflectivity is detected; identifying a reflection-optimized first dielectric grating corresponding to the maximum first reflectivity and a reflection-optimized second dielectric grating corresponding to the maximum second reflectivity; and assembling a diffractive optic comprising the reflection-optimized first dielectric grating and the reflection-optimized second dielectric grating.

### BRIEF DESCRIPTION OF THE DRAWINGS

FIG. 1 is a schematic representation of a solar cell assembly according to the present invention.

FIG. 2 is a schematic representation of one embodiment wherein colors in the blue, green and red range of the visible spectrum are reflected at different angles from a respective first, second and third layer nearest to the surface from which sun light is incident.

FIG. 3 is a schematic representation of a multilayered structure with n+1 layers.

FIG. 4 is schematic representation of a first layer of a diffractive optic comprising protrusions having t-shaped profiles.

FIG. 5 is a schematic representation of an nth layer of a diffractive optic comprising a filling polymer encompassing the protrusions.

FIG. 6 is a reflection spectrum for the embodiment discussed in Example 1 superimposed atop the solar spectrum.

FIG. 7 is a schematic of a diffractive species of Example 1.

FIG. 8 is a reflection spectrum for the embodiment discussed in Example 2.

FIG. 9 is a schematic of a diffractive species of Example 2.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. Other aspects of the disclosure will become apparent by consideration of the detailed description and accompanying drawings.

It is specifically understood that any numerical value recited herein (e.g., ranges) includes all values from the lower value to the upper value, i.e., all possible combinations of numerical values between the lowest value and the highest value enumerated are to be considered to be expressly stated in this application. For example, if a concentration range is stated as 1% to 50%, it is intended that values such as 2% to 40%, 10% to 30%, or 1% to 3%, etc., are expressly enumerated in this specification. These are only examples of what is specifically intended. With respect to amounts of components, all percentages are by weight, unless explicitly indicated otherwise.

As used herein, the term “converter” is intended to represent any means of converting electromagnetic radiation into another form of energy. Examples of converters may include solar cells, thermal baths, photosynthesis cells, and the like.

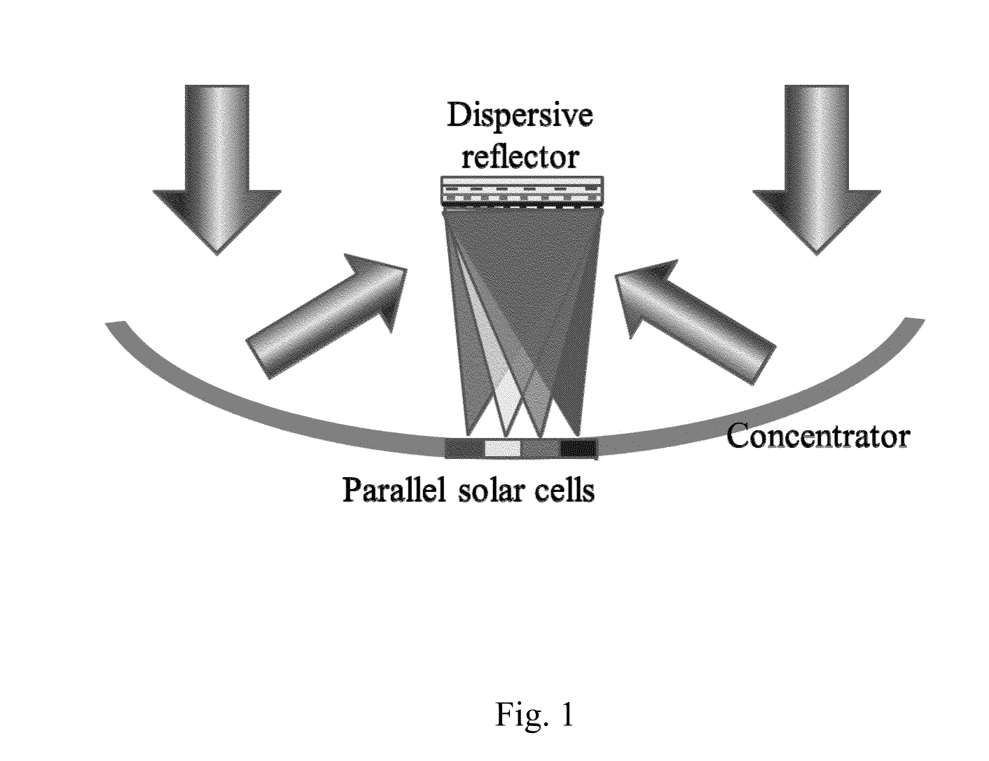

In various embodiments, the invention includes diffractive optics that can be used as part of a solar collector. FIG. 1 shows one example of a solar collector, wherein a concentrator, i.e., a parabolic reflector, directs solar radiation to a dispersive reflector, i.e., a diffractive optic, and directs particular wavelengths toward parallel solar cells, i.e., solar converters arranged in parallel series.

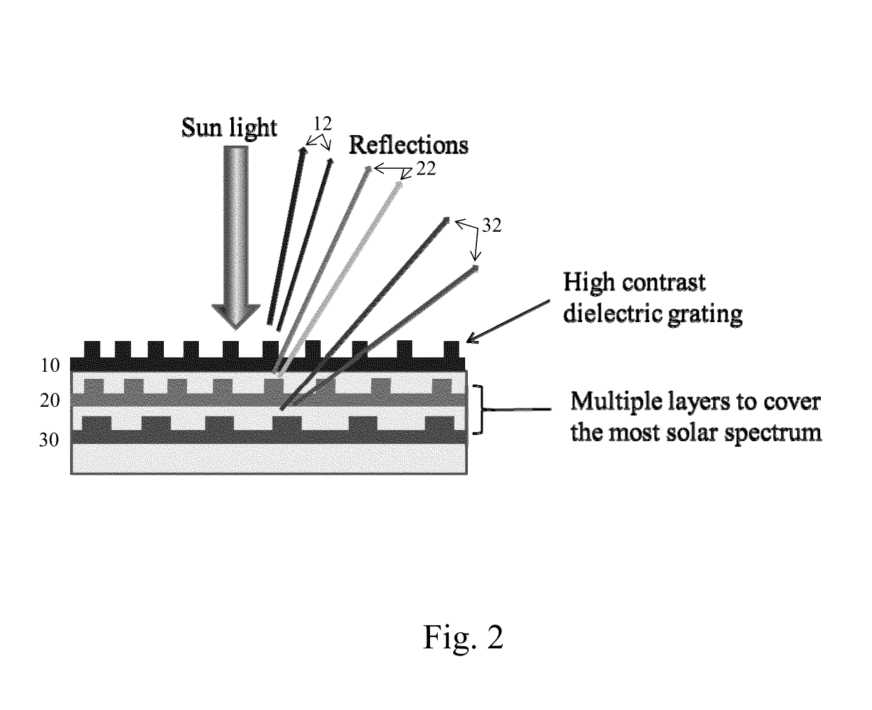

Diffractive optics of the invention typically include a layered structure, wherein shorter wavelength radiation is reflected from layers at or nearer to the surface from which radiation is incident and longer wavelength radiation is reflect from layers farther from the surface from which radiation is incident. FIG. 2 shows a schematic representation of one embodiment wherein colors in the blue range of the visible spectrum 12 are reflected at a certain angle from a first layer 10 nearest to the surface from which sun light is incident, colors from the green range of the visible spectrum 22 are reflected at a certain angle from a second layer 20, and colors from the red range of the visible spectrum 32 are reflected at a certain angle from a third layer 30. The ordering of the layers is believed to be important, due to gratings with smaller features being largely transparent to longer wavelengths.

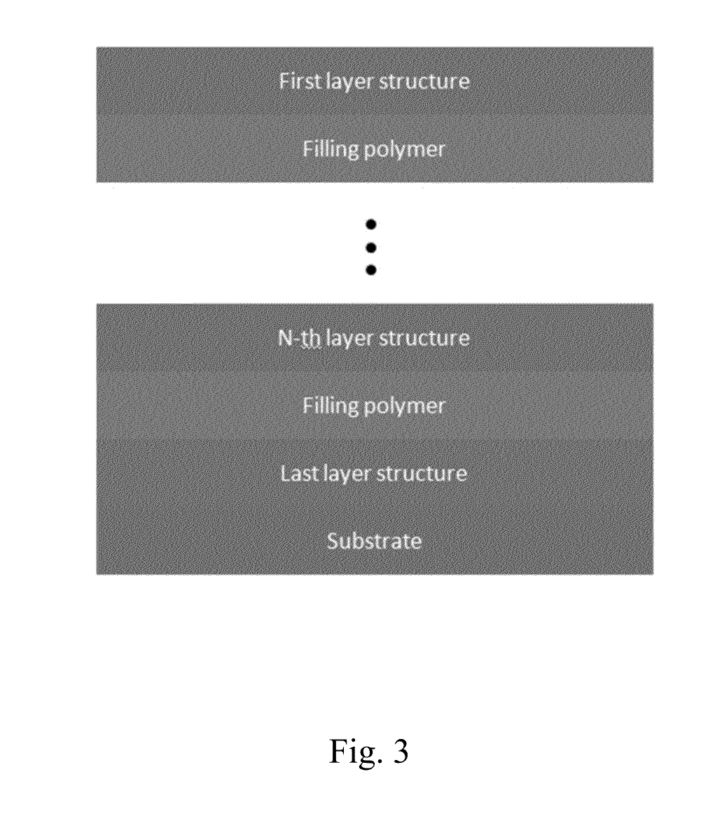

In various embodiments, diffractive optics with a number of layers are disclosed. FIG. 3 shows a generic structure of a multilayered structure with n+1 layers.

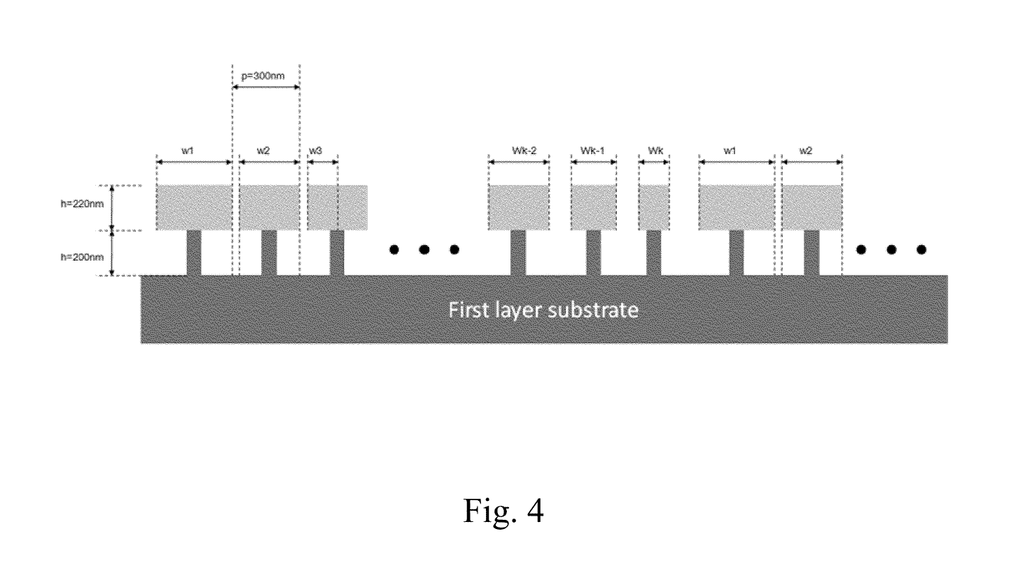

In various embodiments, a first layer of the diffractive optic may comprise protrusions having a t-shaped profile. FIG. 4 shows a schematic representation of a first layer of a diffractive optic comprising protrusions having t-shaped profiles.

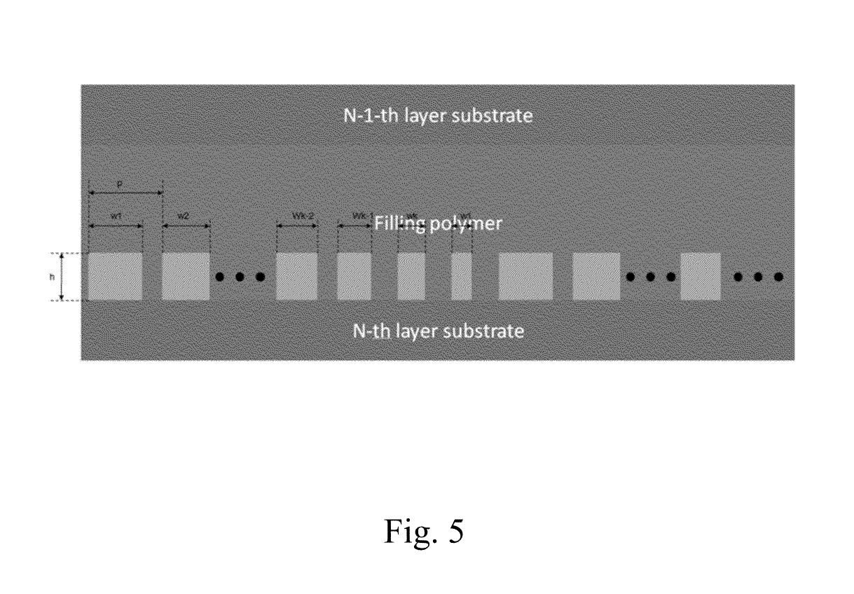

In various embodiments, the nth layer of the diffractive optic may comprise protrusions surrounded with a filling polymer, i.e., a filler material, having suitable optical properties. FIG. 5 shows a schematic representation of an nth layer of a diffractive optic comprising a filling polymer encompassing the protrusions.

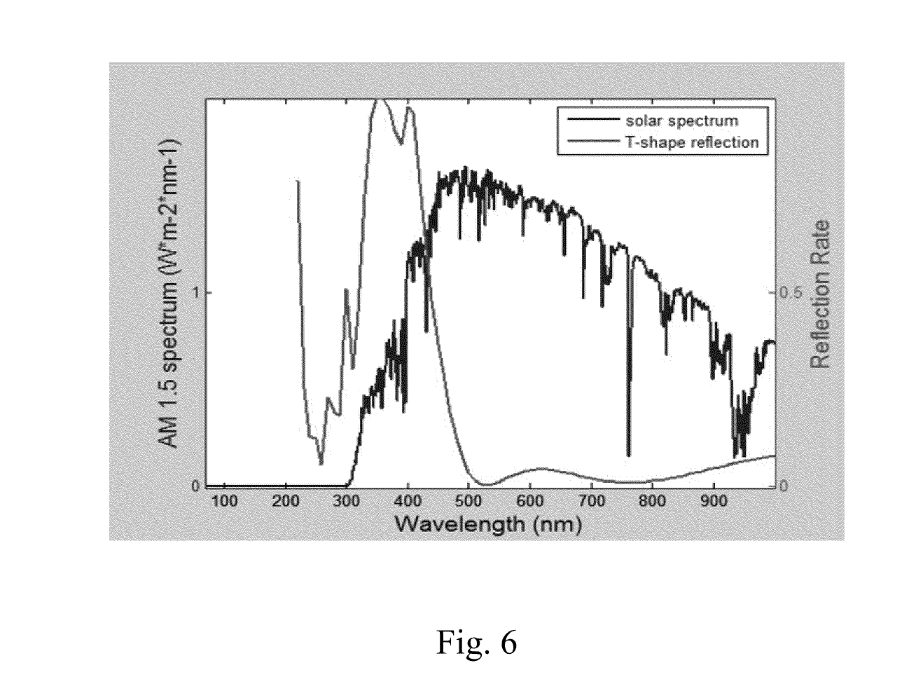

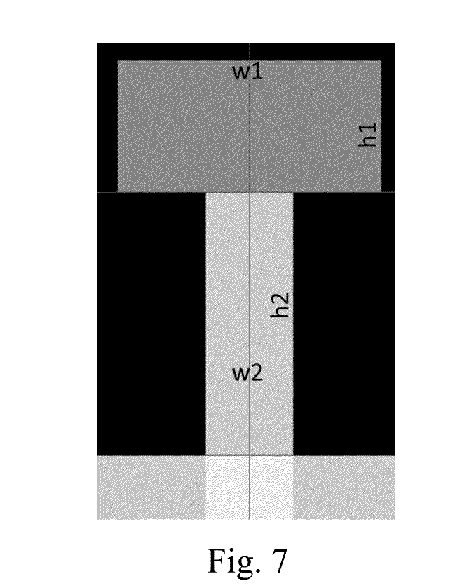

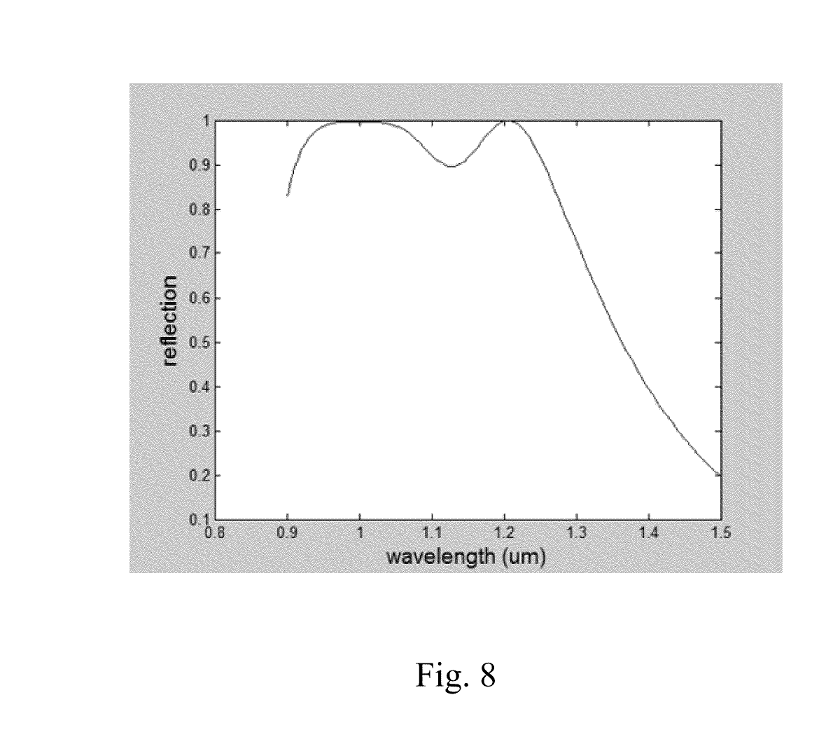

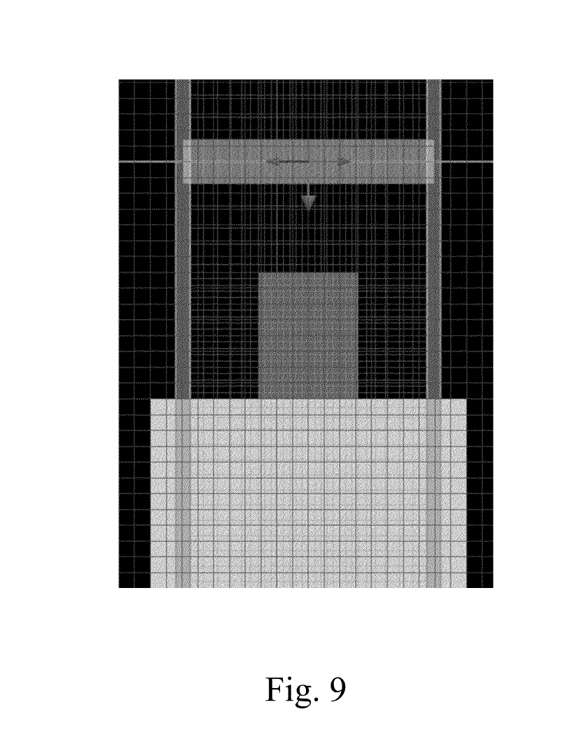

In various embodiments, the reflection spectrum from an individual layer may be broad, i.e., a full-width at half-maximum of greater than about 100 nm. FIG. 6 shows a reflection spectrum for the embodiment represented schematically in FIG. 7 and discussed in Example 1. FIG. 8 shows a reflection spectrum for the embodiment represented schematically in FIG. 9 and discussed in Example 2.

### I. Solar Cell Assembly

In some embodiments, a solar cell assembly for harvesting solar radiation may comprise a diffractive optic; a reflective surface that direct solar radiation into the diffractive optic; a plurality of solar converters including a first converter and a second converter, wherein the diffractive optic directs a first portion of the solar radiation to the first converter and a second portion of the solar radiation to the second converter.

In some embodiments, the first portion may correspond to an energy conversion efficiency of the first converter. In some embodiments, the second portion may correspond to an energy conversion efficiency of the first converter. In some embodiments, an nth portion may correspond to an energy conversion efficiency of an nth converter.

### Reflective Surface

In general, any reflective surface capable of directing solar radiation into the diffraction grating is suitable for use with this invention. In some embodiments, the reflective surface comprises a parabolic reflector.

In some embodiments, the parabolic reflector directs solar radiation into the diffractive optic before the solar radiation has been fully focused. Without wishing to be limited by theory, it is believed that locating the diffractive optic within the focal length of the parabolic mirror provides portions of solar radiation having distinct ranges of wavelengths focusing at distinct points.

### Converter

In general, any converter is suitable for use with this invention.

In some embodiments, the first converter is located at a first angle relative to the diffractive optic. In some embodiments, the second converter is located at a second angle relative to the diffractive optic. In some embodiments, the plurality of solar converters comprises a plurality of parallel solar junctions. In some embodiments, the plurality of solar converters are oriented adjacent to one another. In some embodiments, the first solar converter is located where solar radiation that is reflected at a first angle is incident. In some embodiments, the second solar converter is located where solar radiation that is reflected at a second angle is incident. In general, the nth solar converter is located where solar radiation that is reflected at an nth angle is incident.

### II. Diffractive Optic

In some embodiments, the diffractive optic may comprise a first dielectric grating and a second dielectric grating. In some embodiments, the diffractive optic may further comprise a third dielectric grating, a fourth dielectric grating, and/or further additional dielectric gratings.

In some embodiments, the diffractive optic may comprise a first dielectric grating, a second dielectric grating, and a plurality of dielectric gratings comprising at least a third dielectric grating and a final dielectric grating.

In preferred embodiments, the diffractive optic comprises a first dielectric grating disposed atop a second dielectric grating. In preferred embodiments, the diffractive optic comprises a second dielectric grating disposed atop a third dielectric grating. In preferred embodiments, the diffractive optic comprises a third dielectric grating disposed atop a fourth dielectric grating. In preferred embodiments, the diffractive optic comprises an nth dielectric grating disposed atop a (n+l)th dielectric grating.

In some embodiments, the diffractive optic may be used to reflectively distribute broadband radiation.

Use of the diffractive optic of the present invention to reflectively distribute broadband radiation provides for reflection of a most preferred range of wavelengths first, without passing that range of wavelengths through any solid material. In transmissive optics, by contrast, all ranges of wavelengths must pass through some material, leading to inevitable loss.

In some embodiments, a diffractive optic may reflect electromagnetic radiation as a zeroth order diffraction, a first order diffraction, or a second order diffraction. In preferred embodiments, the diffractive optic may reflect electromagnetic radiation as a zeroth order diffraction or a first order diffraction. In most preferred embodiments, the diffractive optic may reflect electromagnetic radiation as a zeroth order diffraction.

### Broadband Radiation

In some embodiments, the broadband radiation may comprise electromagnetic radiation of any suitable wavelength.

In some embodiments, the broadband radiation may comprise a first portion having a first range of wavelengths and a second portion having a second range of wavelengths. In some embodiments, the broadband radiation may further comprise a third portion having a third range of wavelengths.

In some preferred embodiments, the broadband radiation may comprise a first portion tuned to match an energy conversion efficiency of a first converter and a second portion tuned to match an energy conversion efficiency of a second converter. In some preferred embodiments, the broadband radiation further comprises a third portion tuned to match an energy conversion efficiency of a third converter. In some preferred embodiments, the broadband radiation further comprises a fourth range of wavelengths tuned to match an energy conversion efficiency of a fourth converter. In some embodiments, the broadband radiation may further comprise an nth range of wavelengths tuned to match an energy conversion efficiency of an nth converter.

Broadband radiation may be divided in a number of different ways. In some preferred embodiments, the broadband radiation may comprise a first portion having a first range of wavelengths from about 250 to about 500 nm, a second portion having a second range of wavelengths from about 500 nm to about 900 nm, a third portion having a third range of wavelengths from about 900 nm to about 1.3 μm, and a fourth portion having a fourth range of wavelengths from about 1.3 μm to about 4 μm.

In some embodiments, the range of wavelengths for subsequent portions may or may not overlap. In some embodiments, a portion may have different intensities at different wavelengths within the range of wavelengths.

In some embodiments, a broadband radiation may comprise a plurality of portions and a plurality of ranges of wavelengths.

In a most preferred embodiment, the broadband radiation is solar radiation.

### Range of Wavelengths

In some embodiments, a range of wavelengths may comprise a central wavelength. The term central wavelength is used to describe the wavelength half way between a minimum wavelength and a maximum wavelength, or the mean value of the minimum wavelength and maximum wavelength, or the sum of the minimum wavelength and maximum wavelength divided by two. For example, a range of wavelengths having a minimum wavelength of about 250 nm and a maximum wavelength of about 500 nm has a central wavelength of about 375 nm, a range of wavelengths having a minimum wavelength of about 500 nm and a maximum wavelength of about 900 nm has a central wavelength of about 700 nm, a range of wavelengths having a minimum wavelength of about 900 nm and a maximum wavelength of about 1.3 μm has a central wavelength of about 1.1 μm, and a range of wavelengths having a minimum wavelength of about 1.3 μm and a maximum wavelength of about 4 μm has a central wavelength of about 2.65 μm. In some embodiments, the central wavelength is the wavelength half way between a minimum wavelength at half-maximum and a maximum wavelength at half-maximum.

In preferred embodiments, each range of wavelengths is selected to match an energy conversion efficiency of a unique converter.

### Dielectric Gratings

In some embodiments, a dielectric grating may comprise a material selected from the group consisting of aluminum nitride (AlN), zirconium dioxide (ZrO₂), titanium dioxide (TiO₂), crystalline silicon, amorphous silicon, hafnium (IV) oxide (HfO₂), tantalum pentoxide (Ta₂O₅), silicon dioxide (SiO₂), silicon nitride (Si₃N₄), low-k dielectric materials, plastic, and combinations thereof. In preferred embodiments, the dielectric grating may comprise a material selected from the group consisting of AlN, ZrO₂, TiO₂, crystalline silicon, amorphous silicon, HfO₂, Ta₂O₂, and combinations thereof.

In some embodiments, an nth dielectric grating may comprise an nth plurality of diffractive species having an nth maximum width, an nth maximum width pitch, an nth maximum height, an nth maximum length, an nth maximum length pitch, an nth index of refraction, an nth width chirp function, an nth height chirp function, an nth length chirp function, an nth width pitch chirp function, and an nth length pitch chirp function.

In some embodiments, a diffractive species may comprise a width, a height, a length, and an index of refraction. In some embodiments, a diffractive species may comprise any suitable three-dimensional shape. In preferred embodiments, a diffractive species may comprise a three-dimensional shape selected from the group consisting of a box shape, a spherical shape, a cylindrical shape, a cone shape, and combinations thereof. In some embodiments, a diffractive species may comprise any suitable two-dimensional projection shape. In some embodiments, the two-dimensional projection shape is viewed relative to the plane of the direction the width is measured and the direction the height is measured, the plane of the direction the width is measured and the direction the length is measured, or the plane of the direction the height is measured and the direction the length is measured. Generally, the two-dimensional projection shape may be any solid polygonal shape. In some embodiments, the two-dimensional projection shape may be selected from the group consisting of a quadrangular shape, a T-shape, a circular shape, an ellipse shape, a triangle shape, and combinations thereof. In preferred embodiments, the two-dimensional projection shape may be selected from the group consisting of a quadrangular shape, a t-shape, and combinations thereof. In more preferred embodiments, the two-dimensional projection shape may be selected from the group consisting of a square shape, a rectangular shape, a t-shape, and combinations thereof.

Without wishing to be limited by any theory, it is believed that the combination of the index of refraction and size dimensions will cause dielectric gratings of the present invention to transmit electromagnetic radiation with wavelengths that are larger than the size dimension.

### Index of Refraction

In some embodiments, a plurality of diffractive species may comprise an index of refraction from about 1.5 to about 6. In some embodiments, a plurality of diffractive species may comprise an index of refraction of at least about 1.5, at least about 1.6, at least about 1.7, at least about 1.8, at least about 1.9, at least about 2.0, at least about 2.1, at least about 2.2, at least about 2.3, at least about 2.4, at least about 2.5, at least about 2.6, at least about 2.7, at least about 2.8, at least about 2.9, at least about 3.0, at least about 3.1, at least about 3.2, at least about 3.3, at least about 3.4, at least about 3.5, at least about 3.6, at least about 3.7, at least about 3.8, at least about 3.9, at least about 4.0, at least about 4.5, or at least about 5. In some embodiments, a plurality of diffractive species may comprise an index of refraction of at most about 6.0, at most about 5.5, at most about 5.0, at most about 4.5, at most about 4.0, at most about 3.9, at most about 3.8, at most about 3.7, at most about 3.6, at most about 3.5, at most about 3.4, at most about 3.3, at most about 3.2, at most about 3.1, at most about 3.0, at most about 2.9, at most about 2.8, at most about 2.7, at most about 2.6, at most about 2.5, at most about 2.4, at most about 2.3, at most about 2.2, at most about 2.1, at most about 2.0, at most about 1.9, at most about 1.8, at most about 1.7, or at most about 1.6.

In some embodiments, the nth plurality of diffractive species may comprise an index of refraction from about 1.5 to about 6, so long as the index of refraction of the nth plurality of diffractive species is smaller than the index of refraction of the (n+l)th plurality of diffractive species and is larger than the index of refraction of the (n−1)th plurality of diffractive species.

### Width

The width of a diffractive species is measured perpendicular to the height and length. The maximum width of a plurality of diffractive species is generally equal to or smaller than the maximum length. By definition, the width must be smaller than the width pitch. In order to reflect longer wavelengths, larger widths are required.

In some embodiments, a diffractive species may comprise a width of at least about 1 nm, at least about 5 nm, at least about 10 nm, at least about 25 nm, at least about 50 nm, at least about 60 nm, at least about 70 nm, at least about 80 nm, at least about 90 nm, at least about 100 nm, at least about 110 nm, at least about 120 nm, at least about 125 nm, at least about 130 nm, at least about 140 nm, at least about 150 nm, at least about nm, at least about 160 nm, at least about 170 nm, at least about 175 nm, at least about 180 nm, at least about 190 nm, at least about 200 nm, at least about 210 nm, at least about 220 nm, at least about 230 nm, at least about 240 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 μm, at least about 1 μm, at least about 1.1 μm, at least about 1.2 μm, at least about 1.3 μm, at least about 1.4 μm, or at least about 1.5 μm.

In some embodiments, a diffractive species may comprise a width of at most about 2 lam, at most about 1.9 μm, at most about 1.8 μm, at most about 1.7 μm, at most about 1.6 μm, at most about 1.5 μm, at most about 1.4 μm, at most about 1.3 μm, at most about 1.25 μm, at most about 1.2 μm, at most about 1.15 μm, at most about 1.1 μm, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, at most about 300 nm, at most about 290 nm, at most about 280 nm, at most about 270 nm, at most about 260 nm, at most about 250 nm, at most about 240 nm, at most about 230 nm, at most about 220 nm, at most about 210 nm, at most about 200 nm, at most about 190 nm, at most about 180 nm, at most about 170 nm, at most about 160 nm, at most about 150 nm, at most about 140 nm, at most about 130 nm, at most about 120 nm, or at most about 110 nm.

In some embodiments, the nth plurality of diffractive species may comprise a maximum width of at least about 100 nm, at least about 110 nm, at least about 120 nm, at least about 125 nm, at least about 130 nm, at least about 140 nm, at least about 150 nm, at least about nm, at least about 160 nm, at least about 170 nm, at least about 175 nm, at least about 180 nm, at least about 190 nm, at least about 200 nm, at least about 210 nm, at least about 220 nm, at least about 230 nm, at least about 240 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 lam, at least about 1 μm, at least about 1.1 μm, at least about 1.2 μm, at least about 1.3 μm, at least about 1.4 μm, or at least about 1.5 μm, at least about 1.6 μm, at least about 1.7 μm, at least about 1.8 μm, or at least about 1.9 μm.

In some embodiments, the nth plurality of diffractive species may comprise a maximum width of at most about 2 μm, at most about 1.9 μm, at most about 1.8 μm, at most about 1.7 μm, at most about 1.6 μm, at most about 1.5 μm, at most about 1.4 μm, at most about 1.3 μm, at most about 1.25 μm, at most about 1.2 μm, at most about 1.15 μm, at most about 1.1 lam, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, at most about 300 nm, at most about 290 nm, at most about 280 nm, at most about 270 nm, at most about 260 nm, at most about 250 nm, at most about 240 nm, at most about 230 nm, at most about 220 nm, at most about 210 nm, at most about 200 nm, at most about 190 nm, at most about 180 nm, at most about 170 nm, at most about 160 nm, at most about 150 nm, at most about 140 nm, at most about 130 nm, at most about 120 nm, or at most about 110 nm.

### Width Pitch

The width pitch represents the distance between equivalent points on neighboring diffractive species of the plurality of diffractive species in the width dimension. For example, the width pitch can be measured from the front edge, center or back edge of a diffractive species to the respective front edge, center or back edge of the neighboring diffractive species in the direction in which the width is measured. The width pitch must be greater than the width. The width pitch is generally smaller than the wavelength of electromagnetic radiation reflected by the plurality diffractive species.

In some embodiments, the nth plurality of diffractive species may comprise a width pitch of at least about 100 nm, at least about 110 nm, at least about 120 nm, at least about 125 nm, at least about 130 nm, at least about 140 nm, at least about 150 nm, at least about nm, at least about 160 nm, at least about 170 nm, at least about 175 nm, at least about 180 nm, at least about 190 nm, at least about 200 nm, at least about 210 nm, at least about 220 nm, at least about 230 nm, at least about 240 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 μm, at least about 1 μm, at least about 1.1 μm, at least about 1.2 μm, at least about 1.3 μm, at least about 1.4 μm, or at least about 1.5 μm, at least about 1.6 μm, at least about 1.7 μm, at least about 1.8 μm, or at least about 1.9 μm.

In some embodiments, the nth plurality of diffractive species may comprise a width pitch of at most about 2 μm, at most about 1.9 μm, at most about 1.8 μm, at most about 1.7 μm, at most about 1.6 μm, at most about 1.5 μm, at most about 1.4 μm, at most about 1.3 μm, at most about 1.25 μm, at most about 1.2 μm, at most about 1.15 μm, at most about 1.1 μm, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, at most about 300 nm, at most about 290 nm, at most about 280 nm, at most about 270 nm, at most about 260 nm, at most about 250 nm, at most about 240 nm, at most about 230 nm, at most about 220 nm, at most about 210 nm, at most about 200 nm, at most about 190 nm, at most about 180 nm, at most about 170 nm, at most about 160 nm, at most about 150 nm, at most about 140 nm, at most about 130 nm, at most about 120 nm, or at most about 110 nm.

In some embodiments, the width pitch varies according to the width pitch chirp function.

### Height

The height is measured perpendicular to the width and length. The height may be measured perpendicular to a plane formed by a plurality of diffractive species.

In some embodiments, a diffractive species may comprise a height of at least about 1 nm, at least about 5 nm, at least about 10 nm, at least about 25 nm, at least about 50 nm, at least about 60 nm, at least about 70 nm, at least about 80 nm, at least about 90 nm, at least about 100 nm, at least about 110 nm, at least about 120 nm, at least about 125 nm, at least about 130 nm, at least about 140 nm, at least about 150 nm, at least about nm, at least about 160 nm, at least about 170 nm, at least about 175 nm, at least about 180 nm, at least about 190 nm, at least about 200 nm, at least about 210 nm, at least about 220 nm, at least about 230 nm, at least about 240 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 μm, at least about 1 μm, at least about 1.1 μm, at least about 1.2 μm, at least about 1.3 μm, at least about 1.4 μm, or at least about 1.5 μm.

In some embodiments, a diffractive species may comprise a height of at most about 2 lam, at most about 1.9 μm, at most about 1.8 μm, at most about 1.7 μm, at most about 1.6 μm, at most about 1.5 μm, at most about 1.4 μm, at most about 1.3 μm, at most about 1.25 μm, at most about 1.2 μm, at most about 1.15 μm, at most about 1.1 μm, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, at most about 300 nm, at most about 290 nm, at most about 280 nm, at most about 270 nm, at most about 260 nm, at most about 250 nm, at most about 240 nm, at most about 230 nm, at most about 220 nm, at most about 210 nm, at most about 200 nm, at most about 190 nm, at most about 180 nm, at most about 170 nm, at most about 160 nm, at most about 150 nm, at most about 140 nm, at most about 130 nm, at most about 120 nm, or at most about 110 nm.

In some embodiments, the nth plurality of diffractive species may comprise a maximum height of at least about 100 nm, at least about 110 nm, at least about 120 nm, at least about 125 nm, at least about 130 nm, at least about 140 nm, at least about 150 nm, at least about nm, at least about 160 nm, at least about 170 nm, at least about 175 nm, at least about 180 nm, at least about 190 nm, at least about 200 nm, at least about 210 nm, at least about 220 nm, at least about 230 nm, at least about 240 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 lam, at least about 1 μm, at least about 1.1 μm, at least about 1.2 μm, at least about 1.3 μm, at least about 1.4 μm, or at least about 1.5 μm, at least about 1.6 μm, at least about 1.7 μm, at least about 1.8 μm, or at least about 1.9 μm.

In some embodiments, the nth plurality of diffractive species may comprise a maximum height of at most about 2 μm, at most about 1.9 μm, at most about 1.8 μm, at most about 1.7 μm, at most about 1.6 μm, at most about 1.5 μm, at most about 1.4 μm, at most about 1.3 μm, at most about 1.25 μm, at most about 1.2 μm, at most about 1.15 μm, at most about 1.1 lam, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, at most about 300 nm, at most about 290 nm, at most about 280 nm, at most about 270 nm, at most about 260 nm, at most about 250 nm, at most about 240 nm, at most about 230 nm, at most about 220 nm, at most about 210 nm, at most about 200 nm, at most about 190 nm, at most about 180 nm, at most about 170 nm, at most about 160 nm, at most about 150 nm, at most about 140 nm, at most about 130 nm, at most about 120 nm, or at most about 110 nm.

### Length

The length is measured perpendicular to the width and height. The length is generally equal to or larger than the width. By definition, the length must be smaller than the length pitch. In order to reflect longer wavelengths, for a two-dimensional grating, larger lengths are required.

In general, for a one-dimensional grating, the diffractive species may comprise any length as the one-dimensional grating implies an infinite length dimension.

In some embodiments, for a one-dimensional grating, the nth plurality of diffractive species may comprise a length of at most about 1 m.

In some embodiments, for a two-dimensional grating, a diffractive species may comprise a length of at least about 1 nm, at least about 5 nm, at least about 10 nm, at least about 25 nm, at least about 50 nm, at least about 60 nm, at least about 70 nm, at least about 80 nm, at least about 90 nm, at least about 100 nm, at least about 110 nm, at least about 120 nm, at least about 125 nm, at least about 130 nm, at least about 140 nm, at least about 150 nm, at least about nm, at least about 160 nm, at least about 170 nm, at least about 175 nm, at least about 180 nm, at least about 190 nm, at least about 200 nm, at least about 210 nm, at least about 220 nm, at least about 230 nm, at least about 240 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 lam, at least about 1 μm, at least about 1.1 μm, at least about 1.2 μm, at least about 1.3 μm, at least about 1.4 μm, or at least about 1.5 μm.

In some embodiments, for a two-dimensional grating, a diffractive species may comprise a length of at most about 2 μm, at most about 1.9 μm, at most about 1.8 μm, at most about 1.7 μm, at most about 1.6 μm, at most about 1.5 μm, at most about 1.4 μm, at most about 1.3 μm, at most about 1.25 μm, at most about 1.2 μm, at most about 1.15 μm, at most about 1.1 μm, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, at most about 300 nm, at most about 290 nm, at most about 280 nm, at most about 270 nm, at most about 260 nm, at most about 250 nm, at most about 240 nm, at most about 230 nm, at most about 220 nm, at most about 210 nm, at most about 200 nm, at most about 190 nm, at most about 180 nm, at most about 170 nm, at most about 160 nm, at most about 150 nm, at most about 140 nm, at most about 130 nm, at most about 120 nm, or at most about 110 nm.

In some embodiments, for a two-dimensional grating, the nth plurality of diffractive species may comprise a maximum length of at least about 100 nm, at least about 110 nm, at least about 120 nm, at least about 125 nm, at least about 130 nm, at least about 140 nm, at least about 150 nm, at least about nm, at least about 160 nm, at least about 170 nm, at least about 175 nm, at least about 180 nm, at least about 190 nm, at least about 200 nm, at least about 210 nm, at least about 220 nm, at least about 230 nm, at least about 240 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 μm, at least about 1 μm, at least about 1.1 μm, at least about 1.2 μm, at least about 1.3 μm, at least about 1.4 μm, or at least about 1.5 μm, at least about 1.6 μm, at least about 1.7 μm, at least about 1.8 μm, or at least about 1.9 μm.

In some embodiments, for a two-dimensional grating, the nth plurality of diffractive species may comprise a maximum length of at most about 2 μm, at most about 1.9 μm, at most about 1.8 μm, at most about 1.7 μm, at most about 1.6 μm, at most about 1.5 μm, at most about 1.4 μm, at most about 1.3 μm, at most about 1.25 μm, at most about 1.2 μm, at most about 1.15 lam, at most about 1.1 μm, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, at most about 300 nm, at most about 290 nm, at most about 280 nm, at most about 270 nm, at most about 260 nm, at most about 250 nm, at most about 240 nm, at most about 230 nm, at most about 220 nm, at most about 210 nm, at most about 200 nm, at most about 190 nm, at most about 180 nm, at most about 170 nm, at most about 160 nm, at most about 150 nm, at most about 140 nm, at most about 130 nm, at most about 120 nm, or at most about 110 nm.

In some embodiments, the length varies according to the length chirp function.

### Length Pitch

The length pitch represents the distance between equivalent points on neighboring diffractive species of the plurality of diffractive species in the length dimension. For example, the length pitch can be measured from the front edge, center or back edge of a diffractive species to the respective front edge, center or back edge of the neighboring diffractive species in the direction in which the length is measured. The length pitch must be greater than the length. The length pitch is generally smaller than the wavelength of electromagnetic radiation reflected by the plurality diffractive species.

In some embodiments, for a two-dimensional grating, the nth plurality of diffractive species may comprise a length pitch of at least about 100 nm, at least about 110 nm, at least about 120 nm, at least about 125 nm, at least about 130 nm, at least about 140 nm, at least about 150 nm, at least about nm, at least about 160 nm, at least about 170 nm, at least about 175 nm, at least about 180 nm, at least about 190 nm, at least about 200 nm, at least about 210 nm, at least about 220 nm, at least about 230 nm, at least about 240 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 μm, at least about 1 μm, at least about 1.1 μm, at least about 1.2 μm, at least about 1.3 μm, at least about 1.4 μm, or at least about 1.5 μm, at least about 1.6 μm, at least about 1.7 μm, at least about 1.8 μm, or at least about 1.9 μm.

In some embodiments, for a two-dimensional grating, the nth plurality of diffractive species may comprise a length pitch of at most about 2 μm, at most about 1.9 μm, at most about 1.8 μm, at most about 1.7 μm, at most about 1.6 μm, at most about 1.5 μm, at most about 1.4 lam, at most about 1.3 μm, at most about 1.25 μm, at most about 1.2 μm, at most about 1.15 μm, at most about 1.1 μm, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, at most about 300 nm, at most about 290 nm, at most about 280 nm, at most about 270 nm, at most about 260 nm, at most about 250 nm, at most about 240 nm, at most about 230 nm, at most about 220 nm, at most about 210 nm, at most about 200 nm, at most about 190 nm, at most about 180 nm, at most about 170 nm, at most about 160 nm, at most about 150 nm, at most about 140 nm, at most about 130 nm, at most about 120 nm, or at most about 110 nm.

In some embodiments, the length pitch varies according to the length pitch chirp function.

### Chirp Function

Chirp can generally be described as a distance-varying function. In preferred embodiments, chirp functions are normalized. In general, a property of a diffractive species of a plurality of diffractive species may be determined by multiplying the maximum value of the property of the plurality of diffractive species times the value of the property chirp function at a distance separating the diffractive species from the origin of the property chirp function. In some embodiments, the property chirp function may have an arbitrary origin.

Applying a chirp function to a dielectric grating in embodiments encompassing a computer simulation indicates a computer-based calculation to provide dimensions for diffraction species within a plurality of diffraction species. Applying a chirp function to a dielectric grating in embodiments encompassing fabrication of dielectric gratings indicates that a mathematical calculation is made to provide dimensions for diffraction species within a plurality of diffraction species, and the fabrication of dielectric gratings comprising a plurality of diffraction species of the calculated dimensions.

Different physical dimensions of a plurality of diffractive species may have a chirp function, such as a width chirp function, a height chirp function, a length chirp function, a width pitch chirp function, or a length pitch chirp function.

In some embodiments, the width of a diffractive species of a plurality of diffractive species is determined by multiplying the maximum width of the plurality of diffractive species times the width chirp function at a distance separating the diffractive species from the origin of the width chirp function. In some embodiments, the height of a diffractive species of a plurality of diffractive species is determined by multiplying the maximum height of the plurality of diffractive species times the height chirp function at a distance separating the diffractive species from the origin of the height chirp function. In some embodiments, the length of a diffractive species of a plurality of diffractive species is determined by multiplying the maximum length of the plurality of diffractive species times the length chirp function at a distance separating the diffractive species from the origin of the length chirp function. In some embodiments, the width pitch of a diffractive species of a plurality of diffractive species is determined by multiplying the maximum width pitch of the plurality of diffractive species times the width pitch chirp function at a distance separating the diffractive species from the origin of the width pitch chirp function. In some embodiments, the length pitch of a diffractive species of a plurality of diffractive species is determined by multiplying the maximum length pitch of the plurality of diffractive species times the length pitch chirp function at a distance separating the diffractive species from the origin of the length pitch chirp function.

In some embodiments, the chirp function may comprise a function selected from the group consisting of a linear function, a quadratic function, a cubic function, a continuous function, an analytic function, an arithmetic function, a differentiable function, a smooth function, a periodic function, a monotonic function, an even function, an odd function, and combinations thereof.

In a preferred embodiment, the chirp comprises a combination of at least a periodic function, a linear function, a quadratic function, and a cubic function.

In embodiments where a chirp function comprises an identity function for a particular plurality of diffractive species, the corresponding physical dimension does not vary for said plurality.

### Width Chirp Function

In a most preferred embodiment, the width chirp function may comprise a periodic function with a maximum value of 1 that repeats periodically with a width chirp period.

In general, a smaller width chirp period provides a reflection at a larger angle in the direction in which the width is measured with respect to an incident radiation source, and vice versa.

In some embodiments, the width chirp period is at least about 1 μm, at least about 2 lam, at least about 3 μm, at least about 4 μm, at least about 5 μm, at least about 6 μm, at least about 7 μm, at least about 8 μm, at least about 9 μm, at least about 10 μm, at least about 15 μm, at least about 20 μm, at least about 25 μm, at least about 30 μm, at least about 35 μm, at least about 40 μm, at least about 45 μm, at least about 50 μm, at least about 55 μm, at least about 60 lam, at least about 65 μm, at least about 70 μm, at least about 75 μm, at least about 80 μm, at least about 85 μm, at least about 90 μm, at least about 95 μm, at least about 100 μm, at least about 110 μm, at least about 120 μm, at least about 130 μm, at least about 140 μm, at least about 150 μm, at least about 160 μm, at least about 170 μm, at least about 180 μm, at least about 190 lam, at least about 200 μm, at least about 300 μm, or at least about 400 μm.

In some embodiments, the width chirp period is at most about 500 μm, at most about 450 μm, at most about 400 μm, at most about 375 μm, at most about 350 μm, at most about 325 lam, at most about 300 μm, at most about 290 μm, at most about 280 μm, at most about 270 μm, at most about 260 μm, at most about 250 μm, at most about 240 μm, at most about 230 μm, at most about 220 μm, at most about 210 μm, at most about 200 μm, at most about 190 μm, at most about 180 μm, at most about 170 μm, at most about 160 μm, at most about 150 μm, at most about 140 μm, at most about 130 μm, at most about 120 μm, at most about 110 μm, at most about 100 μm, at most about 95 μm, at most about 90 μm, at most about 85 μm, at most about 80 lam, at most about 75 μm, at most about 70 μm, at most about 65 μm, at most about 60 μm, at most about 55 μm, at most about 50 μm, at most about 45 μm, at most about 40 μm, at most about 35 μm, at most about 30 μm, at most about 25 μm, at most about 20 μm, at most about 15, or at most about 10 μm.

In some embodiments, the width of a diffractive species may be the maximum width times the width chirp function.

### Width Pitch Chirp Function

In a most preferred embodiment, the width pitch chirp function may comprise a periodic function with a maximum value of 1 that repeats periodically with a width pitch chirp period. In general, a smaller width pitch chirp period provides a reflection at a larger angle with respect to an incident radiation source, and vice versa.

In some embodiments, the width pitch chirp period is at least about 1 μm, at least about 2 μm, at least about 3 μm, at least about 4 μm, at least about 5 μm, at least about 6 μm, at least about 7 μm, at least about 8 μm, at least about 9 μm, at least about 10 μm, at least about 15 lam, at least about 20 μm, at least about 25 μm, at least about 30 μm, at least about 35 μm, at least about 40 μm, at least about 45 μm, at least about 50 μm, at least about 55 μm, at least about 60 μm, at least about 65 μm, at least about 70 μm, at least about 75 μm, at least about 80 μm, at least about 85 μm, at least about 90 μm, at least about 95 μm, at least about 100 μm, at least about 110 μm, at least about 120 μm, at least about 130 μm, at least about 140 μm, at least about 150 μm, at least about 160 μm, at least about 170 μm, at least about 180 μm, at least about 190 lam, at least about 200 μm, at least about 300 μm, or at least about 400 μm.

In some embodiments, the width pitch chirp period is at most about 500 μm, at most about 450 μm, at most about 400 μm, at most about 375 μm, at most about 350 μm, at most about 325 μm, at most about 300 μm, at most about 290 μm, at most about 280 μm, at most about 270 μm, at most about 260 μm, at most about 250 μm, at most about 240 μm, at most about 230 μm, at most about 220 μm, at most about 210 μm, at most about 200 μm, at most about 190 μm, at most about 180 μm, at most about 170 μm, at most about 160 μm, at most about 150 μm, at most about 140 μm, at most about 130 μm, at most about 120 μm, at most about 110 μm, at most about 100 μm, at most about 95 μm, at most about 90 μm, at most about 85 μm, at most about 80 μm, at most about 75 μm, at most about 70 μm, at most about 65 μm, at most about 60 μm, at most about 55 μm, at most about 50 μm, at most about 45 μm, at most about 40 μm, at most about 35 μm, at most about 30 μm, at most about 25 μm, at most about 20 lam, at most about 15, or at most about 10 μm.

### Height Chirp Function

In one preferred embodiment, the height chirp function is the identify function.

In another preferred embodiment, the height chirp function may comprise a periodic function with a maximum value of 1 that repeats periodically with a height chirp period.

In some embodiments, the height chirp period is at least about 1 μm, at least about 2 lam, at least about 3 μm, at least about 4 μm, at least about 5 μm, at least about 6 μm, at least about 7 μm, at least about 8 μm, at least about 9 μm, at least about 10 μm, at least about 15 μm, at least about 20 μm, at least about 25 μm, at least about 30 μm, at least about 35 μm, at least about 40 μm, at least about 45 μm, at least about 50 μm, at least about 55 μm, at least about 60 lam, at least about 65 μm, at least about 70 μm, at least about 75 μm, at least about 80 μm, at least about 85 μm, at least about 90 μm, at least about 95 μm, at least about 100 μm, at least about 110 μm, at least about 120 μm, at least about 130 μm, at least about 140 μm, at least about 150 μm, at least about 160 μm, at least about 170 μm, at least about 180 μm, at least about 190 lam, at least about 200 μm, at least about 300 μm, or at least about 400 μm.

In some embodiments, the height chirp period is at most about 500 μm, at most about 450 μm, at most about 400 μm, at most about 375 μm, at most about 350 μm, at most about 325 lam, at most about 300 μm, at most about 290 μm, at most about 280 μm, at most about 270 μm, at most about 260 μm, at most about 250 μm, at most about 240 μm, at most about 230 μm, at most about 220 μm, at most about 210 μm, at most about 200 μm, at most about 190 μm, at most about 180 μm, at most about 170 μm, at most about 160 μm, at most about 150 μm, at most about 140 μm, at most about 130 μm, at most about 120 μm, at most about 110 μm, at most about 100 μm, at most about 95 μm, at most about 90 μm, at most about 85 μm, at most about 80 lam, at most about 75 μm, at most about 70 μm, at most about 65 μm, at most about 60 μm, at most about 55 μm, at most about 50 μm, at most about 45 μm, at most about 40 μm, at most about 35 μm, at most about 30 μm, at most about 25 μm, at most about 20 μm, at most about 15, or at most about 10 μm.

In some embodiments, the height of a diffractive species may be the maximum height times the height chirp function.

### Length Chirp Function

In one preferred embodiment encompassing a one-dimensional grating, the length chirp function is the identity function.

In a preferred embodiment encompassing a two-dimensional grating, the length chirp function may comprise a periodic function with a maximum value of 1 that repeats periodically with a length chirp period.

In general, for a two-dimensional grating, a smaller length chirp period provides a reflection at a larger angle in the direction in which the length is measured with respect to an incident radiation source, and vice versa.

In some embodiments, encompassing a two-dimensional grating, the length chirp period is at least about 1 μm, at least about 2 μm, at least about 3 μm, at least about 4 μm, at least about 5 μm, at least about 6 μm, at least about 7 μm, at least about 8 μm, at least about 9 lam, at least about 10 μm, at least about 15 μm, at least about 20 μm, at least about 25 μm, at least about 30 μm, at least about 35 μm, at least about 40 μm, at least about 45 μm, at least about 50 μm, at least about 55 μm, at least about 60 μm, at least about 65 μm, at least about 70 μm, at least about 75 μm, at least about 80 μm, at least about 85 μm, at least about 90 μm, at least about 95 μm, at least about 100 μm, at least about 110 μm, at least about 120 μm, at least about 130 lam, at least about 140 μm, at least about 150 μm, at least about 160 μm, at least about 170 μm, at least about 180 μm, at least about 190 μm, at least about 200 μm, at least about 300 μm, or at least about 400 μm.

In some embodiments, encompassing a two-dimensional grating, the length chirp period is at most about 500 μm, at most about 450 μm, at most about 400 μm, at most about 375 lam, at most about 350 μm, at most about 325 μm, at most about 300 μm, at most about 290 μm, at most about 280 μm, at most about 270 μm, at most about 260 μm, at most about 250 μm, at most about 240 μm, at most about 230 μm, at most about 220 μm, at most about 210 μm, at most about 200 μm, at most about 190 μm, at most about 180 μm, at most about 170 μm, at most about 160 μm, at most about 150 μm, at most about 140 μm, at most about 130 μm, at most about 120 μm, at most about 110 μm, at most about 100 μm, at most about 95 μm, at most about 90 μm, at most about 85 μm, at most about 80 μm, at most about 75 μm, at most about 70 μm, at most about 65 μm, at most about 60 μm, at most about 55 μm, at most about 50 μm, at most about 45 μm, at most about 40 μm, at most about 35 μm, at most about 30 μm, at most about 25 lam, at most about 20 μm, at most about 15, or at most about 10 μm.

In some embodiments, the length of a diffractive species may be the maximum length times the length chirp function.

### Length Pitch Chirp Function

In one preferred embodiment encompassing a one-dimensional grating, the length pitch chirp function is the identity function.

In a preferred embodiment encompassing a two-dimensional grating, the length pitch chirp function comprises a periodic function with a maximum of 1 that repeats periodically with a length pitch chirp period.

In some embodiments, encompassing a two-dimensional grating, the length pitch chirp period is at least about 1 μm, at least about 2 μm, at least about 3 μm, at least about 4 μm, at least about 5 μm, at least about 6 μm, at least about 7 μm, at least about 8 μm, at least about 9 lam, at least about 10 μm, at least about 15 μm, at least about 20 μm, at least about 25 μm, at least about 30 μm, at least about 35 μm, at least about 40 μm, at least about 45 μm, at least about 50 μm, at least about 55 μm, at least about 60 μm, at least about 65 μm, at least about 70 μm, at least about 75 μm, at least about 80 μm, at least about 85 μm, at least about 90 μm, at least about 95 μm, at least about 100 μm, at least about 110 μm, at least about 120 μm, at least about 130 lam, at least about 140 μm, at least about 150 μm, at least about 160 μm, at least about 170 μm, at least about 180 μm, at least about 190 μm, at least about 200 μm, at least about 300 μm, or at least about 400 μm.

In some embodiments, the length pitch chirp period is at most about 500 μm, at most about 450 μm, at most about 400 μm, at most about 375 μm, at most about 350 μm, at most about 325 μm, at most about 300 μm, at most about 290 μm, at most about 280 μm, at most about 270 μm, at most about 260 μm, at most about 250 μm, at most about 240 μm, at most about 230 μm, at most about 220 μm, at most about 210 μm, at most about 200 μm, at most about 190 μm, at most about 180 μm, at most about 170 μm, at most about 160 μm, at most about 150 μm, at most about 140 μm, at most about 130 μm, at most about 120 μm, at most about 110 μm, at most about 100 μm, at most about 95 μm, at most about 90 μm, at most about 85 μm, at most about 80 μm, at most about 75 μm, at most about 70 μm, at most about 65 μm, at most about 60 μm, at most about 55 μm, at most about 50 μm, at most about 45 μm, at most about 40 μm, at most about 35 μm, at most about 30 μm, at most about 25 μm, at most about 20 lam, at most about 15, or at most about 10 μm.

### First Dielectric Grating

In some embodiments, the first dielectric grating may comprise a material selected from the group consisting of AIN, ZrO₂, TiO₂, SiO₂, Si₃N₄, low-k dielectric materials, plastic, and combinations thereof.

In some embodiments, the first dielectric grating may be adapted to transmit at least about 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, or at least about 95% of the portion of the broadband radiation outside the first range of wavelengths.

In some embodiments, the first dielectric grating may be adapted to transmit at least about 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, or at least about 95% of each of the second through the final range of wavelengths.

### nth Dielectric Grating

In some embodiments, the nth dielectric grating may be adapted to reflect at least about 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, or at least about 95% of a range of wavelengths.

In some embodiments, the nth dielectric grating may be adapted to transmit at least about 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, or at least about 95% of the portion of the broadband radiation outside the nth range of wavelengths.

In some embodiments, the nth dielectric grating may comprise an nth reflection spectrum having a central wavelength of at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 μm, at least about 1 μm, at least about 1.1 μm, at least about 1.2 μm, at least about 1.3 μm, at least about 1.4 μm, or at least about 1.5 μm, at least about 1.6 μm, at least about 1.7 μm, at least about 1.8 μm, or at least about 1.9 μm.

In some embodiments, the nth dielectric grating may comprise an nth reflection spectrum having a central wavelength of at most about 3 μm, at most about 2 μm, at most about 1.9 μm, at most about 1.8 μm, at most about 1.7 μm, at most about 1.6 μm, at most about 1.5 lam, at most about 1.4 μm, at most about 1.3 μm, at most about 1.25 μm, at most about 1.2 μm, at most about 1.15 μm, at most about 1.1 μm, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, or at most about 300 nm.

In some embodiments, the nth dielectric grating may comprise an nth reflection spectrum having a full-width at half-maximum of at least about 50 nm, at least about 60 nm, at least about 70 nm, at least about 80 nm, at least about 90 nm, at least about 100 nm, at least about 150 nm, at least about 200 nm, at least about 300 nm, at least about 400 nm, or at least about 500 nm.

In all embodiments, any reflection spectrum having a central wavelength and a full-width at half-maximum has a minimum wavelength at half-maximum of the central wavelength minus half the full-width at half-maximum and a maximum wavelength at half-maximum of the central wavelength plus half the full-width at half-maximum.

In some embodiments, the nth dielectric grating comprises an nth reflection spectrum having a minimum wavelength at half-maximum of at least about 50 nm, at least about 100 nm, at least about 150 nm, at least about 200 nm, at least about 250 nm, at least about 260 nm, at least about 270 nm, at least about 280 nm, at least about 290 nm, at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 μm, at least about 1 μm, at least about 1.1 μm, at least about 1.2 μm, at least about 1.3 lam, at least about 1.4 μm, or at least about 1.5 μm.

In some embodiments, the nth dielectric grating comprises a reflection spectrum having a minimum wavelength at half-maximum of at most about 1.5 μm, at most about 1.4 μm, at most about 1.3 μm, at most about 1.25 μm, at most about 1.2 μm, at most about 1.15 μm, at most about 1.1 μm, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, at most about 350 nm, at most about 340 nm, at most about 330 nm, at most about 320 nm, at most about 310 nm, or at most about 300 nm, at most about 290 nm, at most about 280 nm, at most about 270 nm, at most about 260 nm, or at most about 250 nm.

In some embodiments, the nth dielectric grating comprises a reflection spectrum having a maximum wavelength at half-maximum of at least about 300 nm, at least about 310 nm, at least about 320 nm, at least about 330 nm, at least about 340 nm, at least about 350 nm, at least about 360 nm, at least about 370 nm, at least about 380 nm, at least about 390 nm, at least about 400 nm, at least about 410 nm, at least about 420 nm, at least about 430 nm, at least about 440 nm, at least about 450 nm, at least about 460 nm, at least about 470 nm, at least about 480 nm, at least about 490 nm, at least about 500 nm, at least about 510 nm, at least about 520 nm, at least about 530 nm, at least about 540 nm, at least about 550 nm, at least about 560 nm, at least about 570 nm, at least about 580 nm, at least about 590 nm, at least about 600 nm, at least about 610 nm, at least about 620 nm, at least about 630 nm, at least about 640 nm, at least about 650 nm, at least about 660 nm, at least about 670 nm, at least about 680 nm, at least about 690 nm, at least about 700 nm, at least about 710 nm, at least about 720 nm, at least about 730 nm, at least about 740 nm, at least about 750 nm, at least about 760 nm, at least about 770 nm, at least about 780 nm, at least about 790 nm, at least about 800 nm, at least about 810 nm, at least about 820 nm, at least about 830 nm, at least about 840 nm, at least about 850 nm, at least about 860 nm, at least about 870 nm, at least about 880 nm, at least about 890 nm, at least about 900 nm, at least about 910 nm, at least about 920 nm, at least about 930 nm, at least about 940 nm, at least about 950 nm, at least about 960 nm, at least about 970 nm, at least about 980 nm, at least about 990 lam, at least about 1 μm, at least about 1.1 μm, at least about 1.2 μm, at least about 1.3 μm, at least about 1.4 μm, or at least about 1.5 μm, at least about 1.6 μm, at least about 1.7 μm, at least about 1.8 μm, or at least about 1.9 μm, at least about 2.0 μm, at least about 2.1 μm, at least about 2.2 μm, at least about 2.3 μm, at least about 2.4 μm, at least about 2.5 μm, at least about 2.6 μm, at least about 2.7 μm, at least about 2.8 μm, at least about 2.9 μm, at least about 3.0 μm, at least about 3.1 μm, at least about 3.2 μm, at least about 3.3 μm, at least about 3.4 μm, or at least about 3.5 μm.

In some embodiments, the nth dielectric grating comprises a reflection spectrum having a maximum wavelength at half-maximum at most about 4 μm, at most about 3.9 μm, at most about 3.8 μm, at most about 3.7 μm, at most about 3.6 μm, at most about 3.5 μm, at most about 3.4 μm, at most about 3.3 μm, at most about 3.2 μm, at most about 3.1 μm, at most about 3.0 μm, at most about 2.9 μm, at most about 2.8 μm, at most about 2.7 μm, at most about 2.6 lam, at most about 2.5 μm, at most about 2.4 μm, at most about 2.3 μm, at most about 2.2 μm, at most about 2.1 μm, at most about 2 μm, at most about 1.9 μm, at most about 1.8 μm, at most about 1.7 μm, at most about 1.6 μm, at most about 1.5 μm, at most about 1.4 μm, at most about 1.3 μm, at most about 1.25 μm, at most about 1.2 μm, at most about 1.15 μm, at most about 1.1 lam, at most about 1.05 μm, at most about 1 μm, at most about 990 nm, at most about 980 nm, at most about 970 nm, at most about 960 nm, at most about 950 nm, at most about 940 nm, at most about 930 nm, at most about 920 nm, at most about 910 nm, at most about 900 nm, at most about 890 nm, at most about 880 nm, at most about 870 nm, at most about 860 nm, at most about 850 nm, at most about 840 nm, at most about 830 nm, at most about 820 nm, at most about 810 nm, at most about 800 nm, at most about 790 nm, at most about 780 nm, at most about 770 nm, at most about 760 nm, at most about 750 nm, at most about 740 nm, at most about 730 nm, at most about 720 nm, at most about 710 nm, at most about 700 nm, at most about 690 nm, at most about 680 nm, at most about 670 nm, at most about 660 nm, at most about 650 nm, at most about 640 nm, at most about 630 nm, at most about 620 nm, at most about 610 nm, at most about 600 nm, at most about 590 nm, at most about 580 nm, at most about 570 nm, at most about 560 nm, at most about 550 nm, at most about 540 nm, at most about 530 nm, at most about 520 nm, at most about 510 nm, at most about 500 nm, at most about 490 nm, at most about 480 nm, at most about 470 nm, at most about 460 nm, at most about 450 nm, at most about 440 nm, at most about 430 nm, at most about 420 nm, at most about 410 nm, at most about 400 nm, at most about 390 nm, at most about 380 nm, at most about 370 nm, at most about 360 nm, or at most about 350 nm.

A percent maximum reflection is the integrated intensity from the minimum wavelength at half-maximum to the maximum wavelength at half-maximum. In some embodiments, the nth dielectric grating comprises a percent maximum reflection of at least about 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, or at least about 95% between the minimum wavelength at half-maximum and the maximum wavelength at half-maximum.

In some embodiments, the nth dielectric grating comprises a percent maximum reflection of at most about 100%, at most about 99%, at most about 98%, at most about 97%, at most about 96%, at most about 95%, at most about 94%, at most about 93%, at most about 92%, at most about 91%, at most about 90%, at most about 89%, at most about 88%, at most about 87%, at most about 86%, at most about 85%, at most about 84%, at most about 83%, at most about 82%, at most about 81%, at most about 80%, at most about 79%, at most about 78%, at most about 77%, at most about 76%, at most about 75%, at most about 74%, at most about 73%, at most about 72%, at most about 71%, at most about 70%, at most about 69%, at most about 68%, at most about 67%, at most about 66%, at most about 65%, at most about 64%, at most about 63%, at most about 62%, at most about 61%, at most about 60%, at most about 59%, at most about 58%, at most about 57%, at most about 56%, at most about 55%, at most about 54%, at most about 53%, at most about 52%, at most about 51%, at most about 50%

In some embodiments, a reflection spectrum may comprise any waveform, including waveforms selected from the group consisting of a Gaussian waveform, a plane wave, a spherical wave, a cylindrical wave, and combinations thereof

### Second, Third, Fourth and Subsequent Dielectric Gratings

In some embodiments, the second, third, fourth and subsequent dielectric gratings may comprise any suitable dielectric grating material for the respective second, third, fourth and subsequent range of wavelengths.

In some embodiments, the second, third, fourth and subsequent dielectric gratings may be adapted to reflect at least about 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, or at least about 95% of a respective second, third, fourth and subsequent range of wavelengths.

### Final Dielectric Grating

In some embodiments, the final dielectric grating may comprise a material selected from the group consisting of crystalline silicon, amorphous silicon, HfO₂, Ta₂O₅, SiO₂, Si₃N₄, low-k dielectric materials, plastic, and combinations thereof.

In general, the final dielectric grating need not have any specific transmission properties, because the final reflection occurs at the final dielectric grating.

### Substrates

In general, an nth substrate may be of any material with low dispersion and optical loss for electromagnetic radiation that is reflected by subsequent dielectric gratings, so long as the nth dielectric grating is sufficiently supported.

In some embodiments, the substrate may comprise a material selected from the group consisting of SiO₂, glass, plastic, Si, metal, paper, and combinations thereof.

In preferred embodiments, the substrates of all layers comprise SiO₂.

In general, since the final reflection from the final layer has already occurred by the time any residual radiation interacts with the final layer substrate, the final layer substrate may be of any material, so long as the final layer is sufficiently supported.

### Filler Material

In general, suitable filler materials may be any material with low dispersion and optical loss for electromagnetic radiation that is reflected by any dielectric grating disposed beyond said filler material in the direction of propagation of the electromagnetic radiation.

In some embodiments, suitable filler material may be selected from the group consisting of vacuum, air, spin-on glass, transparent polymers, transparent plastics, SiO₂, low-k dielectric material, water, oil, solvents, and combinations thereof.

In principle, a filler material capable of properly supporting the layers of the present invention could serve as the layer substrate for each of the layers.

### III. Methods of Designing and Making Diffractive Optics

In some embodiments, in a method of designing a diffractive optic for reflectively distributing a broadband radiation, the method may comprise preparing a plurality of nth dielectric gratings by varying a nth index of refraction from about 1.5 to about 6, varying an nth height from about 20% of the nth minimum wavelength to about 200% of the nth maximum wavelength, varying an nth width pitch from about the nth minimum wavelength divided by the nth index of refraction to about the nth maximum wavelength, and varying an nth width from about 0 to about the nth pitch, wherein varying the nth index of refraction, varying the nth height, varying the nth width pitch, and varying the nth width are performed with a step size sufficient to ensure that a maximum nth reflectivity is detected.

In some embodiments, preparing an nth plurality of dielectric grating may comprise varying an nth height from at least about 20%, at least about 25%, at least about 30%, at least about 35%, at least about 40%, at least about 45%, at least about 50%, at least about 55%, at least about 60%, at least about 65%, at least about 70%, at least about 75%, at least about 80%, at least about 85%, at least about 90%, at least about 95%, at least about 100%, at least about 110%, at least about 120%, at least about 130%, at least about 140%, at least about 150%, at least about 160%, at least about 170%, at least about 180%, at least about 190%, or at least about 200% of the nth minimum wavelength to an nth height of at most about 200%, at most about 190%, at most about 180%, at most about 170%, at most about 160%, at most about 150%, at most about 140%, at most about 130%, at most about 120%, at most about 110%, or at most about 100% of the nth maximum wavelength.

In some embodiments, varying an nth parameter comprises a narrower range that is centered at the same point, wherein the range is at most about 99%, at most about 98%, at most about 97%, at most about 96%, at most about 95%, at most about 94%, at most about 93%, at most about 92%, at most about 91%, at most about 90%, at most about 89%, at most about 88%, at most about 87%, at most about 86%, at most about 85%, at most about 84%, at most about 83%, at most about 82%, at most about 81%, at most about 80%, at most about 79%, at most about 78%, at most about 77%, at most about 76%, at most about 75%, at most about 74%, at most about 73%, at most about 72%, at most about 71%, at most about 70%, at most about 69%, at most about 68%, at most about 67%, at most about 66%, at most about 65%, at most about 64%, at most about 63%, at most about 62%, at most about 61%, at most about 60%, at most about 59%, at most about 58%, at most about 57%, at most about 56%, at most about 55%, at most about 54%, at most about 53%, at most about 52%, at most about 51%, or at most about 50%, at most about 49%, at most about 48%, at most about 47%, at most about 46%, at most about 45%, at most about 44%, at most about 43%, at most about 42%, at most about 41%, at most about 40%, at most about 39%, at most about 38%, at most about 37%, at most about 36%, at most about 35%, at most about 34%, at most about 33%, at most about 32%, at most about 31%, at most about 30%, at most about 29%, at most about 28%, at most about 27%, at most about 26%, at most about 25%, at most about 24%, at most about 23%, at most about 22%, at most about 21%, at most about 20%, at most about 19%, at most about 18%, at most about 17%, at most about 16%, at most about 15%, at most about 14%, at most about 13%, at most about 12%, at most about 11%, at most about 10%, at most about 9%, at most about 8%, at most about 7%, at most about 6%, at most about 5%, at most about 4%, at most about 3%, at most about 2%, at most about 1%, at most about 0.1%, or at most about 0.01% of the broadest range over which the nth parameter is varied.

In some embodiments, the method may comprise identifying a reflection-optimized nth dielectric grating corresponding to the maximum nth reflectivity. In some embodiments, the method may comprise assembling a diffractive optic comprising the reflection-optimized nth dielectric grating.

The method may further comprise applying an nth width chirp function and an nth width pitch chirp function to the reflection-optimized nth dielectric grating and varying the nth width chirp function and nth width pitch chirp function to provide an angle-optimized nth dielectric grating comprising at least about 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, at least about 95%, at least about 96%, at least about 97%, at least about 98%, or at least about 99% of the maximum nth reflectivity at an nth angle.

The method may further comprise applying an nth length chirp function and an nth length pitch chirp function to the reflection-optimized nth dielectric grating and varying the nth length chirp function and nth length pitch chirp function to provide an angle-optimized nth dielectric grating comprising at least 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, at least about 95%, at least about 96%, at least about 97%, at least about 98%, or at least about 99% of the maximum nth reflectivity at an nth angle.

The method may further comprise applying an nth width chirp function to the reflection-optimized nth dielectric grating and varying the nth width chirp function to provide an angle-optimized nth dielectric grating comprising at least about 25%, at least about 26%, at least about 27%, at least about 28%, at least about 29%, at least about 30%, at least about 31%, at least about 32%, at least about 33%, at least about 34%, at least about 35%, at least about 36%, at least about 37%, at least about 38%, at least about 39%, at least about 40%, at least about 41%, at least about 42%, at least about 43%, at least about 44%, at least about 45%, at least about 46%, at least about 47%, at least about 48%, at least about 49%, at least about 50%, at least about 51%, at least about 52%, at least about 53%, at least about 54%, at least about 55%, at least about 56%, at least about 57%, at least about 58%, at least about 59%, at least about 60%, at least about 61%, at least about 62%, at least about 63%, at least about 64%, at least about 65%, at least about 66%, at least about 67%, at least about 68%, at least about 69%, at least about 70%, at least about 71%, at least about 72%, at least about 73%, at least about 74%, at least about 75%, at least about 76%, at least about 77%, at least about 78%, at least about 79%, at least about 80%, at least about 81%, at least about 82%, at least about 83%, at least about 84%, at least about 85%, at least about 86%, at least about 87%, at least about 88%, at least about 89%, at least about 90%, at least about 91%, at least about 92%, at least about 93%, at least about 94%, at least about 95%, at least about 96%, at least about 97%, at least about 98%, or at least about 99% of the maximum nth reflectivity at an nth angle.

The methods described herein may have all steps performed on a computer.

The methods described herein may have all steps performed by fabricating and testing diffractive optics. The methods described herein may have some steps performed on a computer and some steps performed by fabricating and testing diffractive optics.

In some embodiments, the methods of designing diffractive optics may comprise a method of designing diffractive optics wherein all steps may be performed by fabricating and testing diffractive optics based upon a set of initial parameters, wherein the set of initial parameters may be determined by the methods of designing diffractive optics described herein wherein all steps are performed on a computer.

In some embodiments, diffractive optics described herein may be fabricated by any suitable means known to one of skill in the art. Suitable fabrication methods include nanoimprint, roll-to-roll nanoimprint, injection molding, roll-to-roll printing, photolithography, electron beam lithography, focused ion beam lithography, and combinations thereof.

### Unpolarized Diffractive Optics

The principles of the invention described herein for one-dimensional diffractive optics and polarized radiation apply equally well to unpolarized or two-dimensional diffractive optics.

In general, any two-dimensional pattern suitable for preparing an unpolarized diffractive optic can serve as the diffraction pattern for the diffractive optics of the present invention. Suitable two-dimensional patterns include a square grid, a hex grid, a quasi-crystal grid, and combinations thereof

### Examples

Exemplary embodiments of the present invention are provided in the following examples. The following examples are presented to illustrate the present invention and to assist one of ordinary skill in making and using the same. The examples are not intended in any way to otherwise limit the scope of the invention.

### Example 1

### A Plurality of T-shape Diffractive Species

A plurality oft-shape diffractive species of the shape shown in FIG. 7 and having infinite length were prepared with varying pitch, varying width (w1) and varying height (h1) of the head of the t-shape and varying width (w2) and varying height (h2) of the base of the t-shape. The head of the t-shape was simulated ZrO₂ having an index of refraction of about 2.65 and the base of the t-shape and substrate were simulated SiO₂ having an index of refraction of about 1.55. The parameter space for pitch, w1, h1, w2 and h2 was scanned to determine an optimal orientation for achieving high reflection of the low-wavelength portion of the solar spectrum with at least 100 nm full-width at half-maximum. The optimal orientation was a width pitch of 300 nm, a width (w1) of the head of the t-shape of 110 nm, a height (h1) of the head of the t-shape of 220 nm, a width (w2) of the base of the t-shape of 36 nm and a height (h2) of the base of the t-shape of 300 nm. The simulated reflection spectrum is shown in FIG. 7.

### Example 2

### A Plurality of Rectangular Shape Diffractive Species

A plurality of rectangular shape diffractive species of the shape shown in FIG. 9 and having infinite length were prepared with varying width pitch, varying width and varying height. The diffractive species was simulated ZrO₂ having an index of refraction of about 2.65 and the substrate was simulated SiO₂ having an index of refraction of about 1.55. The parameter space for pitch, width and height was scanned to determine the optimal orientation for achieving high reflection of the high-wavelength portion of the solar spectrum, with at least 300 nm full-width at half maximum. The optimal orientation was a width pitch of 520 nm, a width of 240 nm, and a height of 350 nm. The simulated reflection spectrum is shown in FIG. 9.

We claim:

1. A solar cell assembly for harvesting solar radiation comprising:
a diffractive optic;
a reflective surface that directs solar radiation to the diffractive optic; and
a plurality of solar converters including a first converter having a first energy conversion efficiency and a second converter having a second energy conversion efficiency;
wherein the diffractive optic directs a first portion of the solar radiation to the first converter and a second portion of the solar radiation to the second converter.

2. The solar cell assembly of claim 1, wherein the reflective surface comprises a parabolic reflector.

3. The solar cell assembly of claim 1, wherein the diffractive optic comprises a plurality of dielectric gratings including a first dielectric grating and a second dielectric grating.

4. The solar cell assembly of claim 3, wherein the first dielectric grating comprises a first plurality of diffractive species, and the second dielectric grating comprises a second plurality of diffractive species, the first and second plurality of diffractive species each independently having an index of refraction, a width, a width pitch, a height, a length, a length pitch, a width chirp function, a width pitch chirp function, a height chirp function, a length chirp function, and a length pitch chirp function, and wherein the first and second plurality of diffractive species are separated by a height pitch.

5. The solar cell assembly of claim 4, wherein the index of refraction of the first plurality of diffractive species is less than the index of refraction of the second plurality of diffractive species.

6. The solar cell assembly of claim 4, wherein the first dielectric grating comprises a first chirp function and the second dielectric grating comprises a second chirp function.

7. The solar cell assembly of claim 3, wherein the first dielectric grating reflects the first portion of solar radiation, the first portion of solar radiation having a first range of wavelengths, and wherein the second dielectric grating reflects the second portion of solar radiation, the second portion of solar radiation having a second range of wavelengths different from the first range of wavelengths.

8. The solar cell assembly of claim 7, wherein the first conversion efficiency overlaps with the first range of wavelengths and the second conversion efficiency overlaps with the second range of wavelengths.

9. The solar cell assembly of claim 8, the first range of wavelengths comprising a first central wavelength, the second range of wavelengths comprising a second central wavelength, wherein the second central wavelength is longer than the first central wavelength.

10. The solar cell assembly of claim 9, wherein the dielectric gratings are arranged in layers and wherein solar radiation enters the diffractive optic at the first dielectric grating.

11. The solar cell assembly of claim 1, wherein the plurality of solar converters comprise a plurality of parallel solar junctions oriented adjacent to one another.

12. The solar cell assembly of claim 1, wherein the first portion of solar radiation is reflected at a first angle and the second portion of solar radiation is reflected at a second angle different from the first angle.

13. The solar cell assembly of claim 1, wherein the first solar converter is located where solar radiation reflected at the first angle is incident and the second solar converter is located where solar radiation reflected at the second angle is incident.

14. A diffractive optic for reflectively distributing a broadband radiation, the broadband radiation comprising a first range of wavelengths having a first central wavelength and a second range of wavelengths having a second central wavelength longer than the first central wavelength, the diffractive optic comprising:
a first dielectric grating through which the broadband radiation enters the diffractive optic, the first dielectric grating adapted to reflect at least about 25% of the first range of wavelengths and transmit at least about 25% of the second range of wavelengths; and
a second dielectric grating adapted to reflect at least about 25% of the second range of wavelengths.

15. The diffractive optic of claim 13, the broadband radiation further comprising a third range of wavelengths, the third range of wavelengths having a third central wavelength longer than the second central wavelength, the first and second dielectric gratings adapted to transmit at least about 90% of the third range of wavelengths, the diffractive optic further comprising:
a third dielectric grating adapted to reflect at least about 25% of the third range of wavelengths.

16. The diffractive optic of claim 13, the broadband radiation further comprising a plurality of ranges of wavelengths including at least a third range of wavelengths and a final range of wavelengths, the third range of wavelengths having a third central wavelength longer than the second central wavelength, each subsequent range of wavelengths having a subsequent central wavelength longer than the central wavelength of the preceding range of wavelengths, and the final range of wavelengths having a final central wavelength longer than the first, second, third or any subsequent central wavelength, the first and second dielectric grating adapted to provide transmission of at least about 25% of the plurality of ranges of wavelengths, and the diffractive optic further comprising:
a plurality of dielectric gratings comprising at least a third dielectric grating and a final dielectric grating,
the third dielectric grating adapted to reflect at least about 25% of the third range of wavelengths and transmit at least about 25% of each subsequent range of wavelengths, and
each subsequent dielectric grating adapted to reflect at least about 25% of a corresponding subsequent range of wavelengths and transmit at least about 25%, and
the final dielectric grating adapted to reflect at least about 25% of the final range of wavelengths.

17. The diffractive optic of claim 13, wherein the first dielectric grating is adapted to reflect the first range of wavelengths at a first angle and the second dielectric grating is adapted to reflect the second range of wavelengths at a second angle, wherein the second angle is different than the first angle.

18. The diffractive optic of claim 14, wherein the first dielectric grating is adapted to reflect the first range of wavelengths at a first angle, the second dielectric grating is adapted to reflect the second range of wavelengths at a second angle, and the third dielectric grating is adapted to reflect the third range of wavelengths at a third angle, wherein the first, second and third angle are different.

19. The diffractive optic of claim 13, wherein the first range of wavelengths is from about 250 nm to about 500 nm and wherein the second range of wavelengths is from about 900 nm to about 1300 nm.

20. The diffractive optic of claim 13, wherein the first dielectric grating comprises a substrate having a plurality of projections thereon.

21. The diffractive optic of claim 20, wherein each of the plurality of projections has a T-shaped cross-sectional profile.

22. The diffractive optic of claim 21, wherein at least two of the T-shaped cross-sectional profiles of the projections have different widths.

23. A method of designing a diffractive optic for reflectively distributing a broadband radiation, the broadband radiation comprising a first range of wavelengths having a first minimum wavelength, a first maximum wavelength and a first central wavelength and a second range of wavelengths having a second minimum wavelength, a second maximum wavelength and a second central wavelength longer than the first minimum wavelength, first maximum wavelength and first central wavelength, respectively, the method comprising:
preparing a plurality of first dielectric gratings by varying a first index of refraction from about 1.5 to about 6, varying a first height from about 20% of the first minimum wavelength to about 200% of the first maximum wavelength, varying a first width pitch from about the first minimum wavelength divided by the first index of refraction to about the first maximum wavelength, and varying a first width from about 0 to about the first pitch, wherein varying the first index of refraction, varying the first height, varying the first width pitch, and varying the first width are performed with a step size sufficient to ensure that a maximum first reflectivity is detected;
preparing a plurality of second dielectric gratings by varying a second index of refraction from about 1.5 to about 6, varying a second height from about 20% of the second minimum wavelength to about 200% of the second maximum wavelength, varying a second pitch from about the second minimum wavelength divided by the second index of refraction to about the second maximum wavelength, and varying a second width from about 0 to about the second width pitch, wherein varying the second index of refraction, varying the second height, varying the second pitch, and varying the second width are performed with a step size sufficient to ensure that a maximum second reflectivity is detected;
identifying a reflection-optimized first dielectric grating corresponding to the maximum first reflectivity and a reflection-optimized second dielectric grating corresponding to the maximum second reflectivity; and
assembling a diffractive optic comprising the reflection-optimized first dielectric grating and the reflection-optimized second dielectric grating.

24. The method of claim 23, further comprising applying a first width chirp function and a first width pitch chirp function to the reflection-optimized first dielectric grating and varying the first width chirp function and first width pitch chirp function to provide an angle-optimized first dielectric grating comprising at least about 90% of the maximum first reflectivity at a first angle, and applying a second width chirp function and a second width pitch chirp function to the reflection-optimized second dielectric grating and varying the second width chirp function and second width pitch chirp function to provide an angle-optimized second dielectric grating comprising at least about 90% of the maximum second reflectivity at a second angle, wherein the second angle is different than the first angle.

25. The method of claim 23, wherein one or more of the first width chirp function, the first width pitch chirp function, the second width chirp function, and the second width pitch chirp function is a periodic function.

26. The method of claim 25, the first width chirp function comprising a first width chirp period from about 1 μm to about 500 μm, the first width pitch chirp function comprising a first width pitch chirp period of from about 1 μm to about 500 μm, the second width chirp function comprising a second width chirp period of from about 1 μm to about 500 μm and the second width pitch chirp function comprising a second width pitch chirp period of from about 1 μm to about 500 μm.

27. The method of claim 23, wherein all of the steps are performed on a computer.

28. The method of claim 23, wherein the preparing and assembling steps comprise a fabrication method selected from the group consisting of nanoimprint, roll-to-roll nanoimprint, injection molding, roll-to-roll printing, photolithography, electron beam lithography, focused ion beam lithography, and combinations thereof.
